(19) United States
(12) Patent Application Publication
(10) Pub. No.: US 2025/0098485 A1
(43) Pub. Date: Mar. 20, 2025

(54) DISPLAYING BASE PLATE AND DISPLAYING DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Ying Liu, Beijing (CN); Bo Zhang, Beijing (CN); Xin Jin, Beijing (CN); Lei Fan, Beijing (CN); Chunfang Fan, Beijing (CN); Fei Liu, Beijing (CN); Liangyun Li, Beijing (CN); Qinbo Ren, Beijing (CN); Yingchang Gao, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 18/565,294

(22) PCT Filed: May 29, 2023
(86) PCT No.: PCT/CN2023/096939

§ 371 Date: Nov. 29, 2023

(30) Foreign Application Priority Data
Jun. 20, 2022 (CN) 202210698193.7

(51) Int. Cl. H10K 59/80; H10K 59/40

(52) U.S. Cl. CPC H10K 59/873; H10K 59/40

(57) ABSTRACT

The present application provides a displaying base plate and a displaying device, which relate to the technical field of displaying. The displaying base plate can effectively reduce the width of the non-displaying region, so as to realize a narrow border frame, and accordingly increase the screen-to-body ratio. The displaying base plate includes: a displaying region; and a non-displaying region surrounding the displaying region, wherein the non-displaying region includes a first dam region, the first dam region surrounds the displaying region; and the first dam region includes a dam, at least one blocking unit located at one side of the dam away from the displaying region, the dam and the blocking unit are disposed within at least a part of the first dam region, and the blocking unit is patterned.

### CROSS REFERENCE TO RELEVANT APPLICATIONS

The present application claims the priority of the Chinese patent application filed on Jun. 20, 2022 before the Chinese Patent Office with the application number of 202210698193.7 and the title of “DISPLAYING BASE PLATE AND DISPLAYING DEVICE”, which is incorporated herein in its entirety by reference.

### TECHNICAL FIELD

The present application relates to the technical field of displaying and, more particularly, to a displaying base plate and a displaying device.

### BACKGROUND

With the development of science and technology, organic light emitting diode (OLED) displaying devices are applied more and more extensively. All of the dams and the metal wires may be disposed within the non-displaying region.

### SUMMARY

The embodiments of the present application employ the following technical solutions:

In an aspect, a displaying base plate is provided, wherein the displaying base plate includes: a displaying region; and a non-displaying region surrounding the displaying region, wherein the non-displaying region includes a first dam region, the first dam region surrounds the displaying region; and
the first dam region includes a dam, at least one blocking unit located at one side of the dam away from the displaying region, the dam and the blocking unit are disposed within at least a part of the first dam region, and the blocking unit is patterned.

Optionally, the first dam region includes one dam.

Optionally, the non-displaying region further includes a driving-circuit region, and the driving-circuit region is located at one side of the first dam region away from the displaying region; and
the dam and the blocking unit are disposed at least one side of the first dam region close to the driving-circuit region.

Optionally, the dam and the blocking unit are disposed within a whole of the first dam region, and surround the displaying region.

Optionally, the blocking unit among the at least one blocking unit adjacent to the dam is connected to the dam.

Optionally, the blocking unit includes a patterned protrusion.

Optionally, the non-displaying region further includes a substrate, and the patterned protrusion is disposed on the substrate; and
the protrusion includes a first planarization part and/or a first pixel defining part.

Optionally, when the protrusion includes the first planarization part, the first planarization part is patterned; or
when the protrusion includes the first pixel defining part, the first pixel defining part is patterned.

Optionally, when the protrusion includes the first planarization part and the first pixel defining part, the protrusion includes the first planarization part and the first pixel defining part that are arranged in layer configuration on the substrate, and the first planarization part is patterned and/or the first pixel defining part is patterned.

Optionally, the non-displaying region further includes a packaging layer disposed at one side of the patterned protrusion away from the substrate, and the packaging layer covers the protrusion.

Optionally, the first dam region includes two blocking units.

Optionally, a shape of an orthographic projection of the patterned protrusion in a direction perpendicular to the substrate includes a planar shape or an annular shape.

Optionally, when the shape of the orthographic projection of the patterned protrusion in the direction perpendicular to the substrate includes the annular shape, the dam region includes a plurality of patterned protrusions, and at least some neighboring patterned protrusions are connected.

Optionally, a range of a height of a cross section of the patterned protrusion perpendicular to the substrate is 1.5-3 μm.

Optionally, a range of a width of the orthographic projection of the patterned protrusion in the direction perpendicular to the substrate is 11-25 μm.

Optionally, when the shape of the orthographic projection of the patterned protrusion in the direction perpendicular to the substrate includes the annular shape, a range of a width of an inner ring of the annular shape in a direction parallel to the substrate is 5-15 μm.

Optionally, the non-displaying region further includes a crack dam region, and the crack dam region surrounds the first dam region, and is broken within the driving-circuit region; and
the crack dam region includes at least one slot, and the slot surrounds the first dam region, and is broken within the driving-circuit region.

Optionally, the non-displaying region further includes a buffer layer, a gate insulating layer and an inter-layer-medium layer that are arranged in layer configuration; all of the inter-layer-medium layer, the gate insulating layer and the buffer layer are located within the displaying region, the first dam region and the crack dam region; and
the slot extends throughout at least a part of the inter-layer-medium layer that is located within the crack dam region.

Optionally, the displaying base plate further includes a substrate, and a driving unit and a touch unit that are disposed on the substrate; and
the driving unit is located within the displaying region, and the touch unit is located within the displaying region and the non-displaying region, and covers the driving unit.

Optionally, the touch unit includes a first touch layer, a first insulating layer, a second touch layer and a second insulating layer that are arranged in layer configuration on the driving unit; both of the first touch layer and the second touch layer are located within the displaying region, and the first insulating layer and the second insulating layer are located within the displaying region and the non-displaying region; and
one of the first touch layer and the second touch layer is a metal-grid electrode layer, and the other is a bridging metal layer.

In another aspect, a displaying device is provided, wherein the displaying device includes the displaying base plate stated above.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the present application or the prior art, the figures that are required to be used to describe the embodiments or the prior art will be briefly described below. Apparently, the figures that are described below are merely some embodiments of the present application, and a person skilled in the art can obtain other figures according to these figures without paying creative work.

FIG. 1 is a schematic diagram of a structure of a displaying base plate in the related art;

FIG. 2 is a diagram of Ink cut-off in the related art;

FIG. 3 is a diagram of another Ink cut-off in the related art;

FIG. 4 is a top view of a displaying base plate according to an embodiment of the present application;

FIG. 5 is a schematic diagram of a structure of a displaying base plate according to an embodiment of the present application;

FIG. 6 is a schematic diagram of a local structure of a displaying base plate according to an embodiment of the present application;

FIG. 7 is a schematic diagram of a local structure of a displaying base plate according to another embodiment of the present application;

FIG. 8 is a schematic diagram of a local structure of a displaying base plate according to yet another embodiment of the present application;

FIG. 9 is a cross-sectional view of a patterned protrusion according to an embodiment of the present application;

FIG. 10 is a schematic diagram of a structure of a displaying base plate according to an embodiment of the present application;

FIG. 11 is a schematic diagram of a structure of a touch unit and an anti-static layer according to an embodiment of the present application; and

FIG. 12 is a schematic diagram of a structure of a touch unit according to an embodiment of the present application.

### DETAILED DESCRIPTION

The technical solutions of the embodiments of the present application will be clearly and completely described below in combination with the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

In the embodiments of the present application, terms such as “first” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

In the embodiments of the present application, the meaning of “at least one” is “one or more”, unless explicitly and particularly defined otherwise.

In the embodiments of the present application, the terms that indicate orientation or position relations, such as “upper”, are based on the orientation or position relations shown in the drawings, and are merely for conveniently describing the present application and simplifying the description, rather than indicating or implying that the device or element must have the specific orientation and be constructed and operated according to the specific orientation. Therefore, they should not be construed as a limitation to the present application.

In recent years, OLED displaying devices have become a novel display product that is very popular in domestic and abroad. That is because OLED displaying devices have the advantages such as self-illumination, a wide visual angle, a short reaction time, a high luminous efficiency, a wide color gamut and a low operating voltage.

FIG. 1 shows a local structure of an OLED displaying device in the related art. Referring to FIG. 1, the OLED displaying device includes a displaying region AA and a non-displaying region BB connected to the displaying region AA. The non-displaying region BB includes a polyimide (PI) layer 1, and a first gate line 2, a second gate line 3, an ILD (Inter Level Dielectric) layer 4, a first PLN (Planarization) layer 5, an SD (source-drain) layer 6, a second PLN layer 7, a pixel define layer (PDL) layer 8 and a first chemical vapor deposition (CVD) layer 9 that are arranged in layer configuration on the PI layer 1. In the present OLED displaying devices, referring to FIG. 1, usually an ink jet printing (IJP) layer 10 is disposed on the first CVD layer 9, wherein the material of the IJP layer 10 is an organic material, for example, an ink, and a second CVD layer (not shown in the figure) is fabricated on the IJP layer 10, thereby the packaging of the OLED displaying device by using the first CVD layer 9, the IJP layer 10 and the second CVD layer is realized.

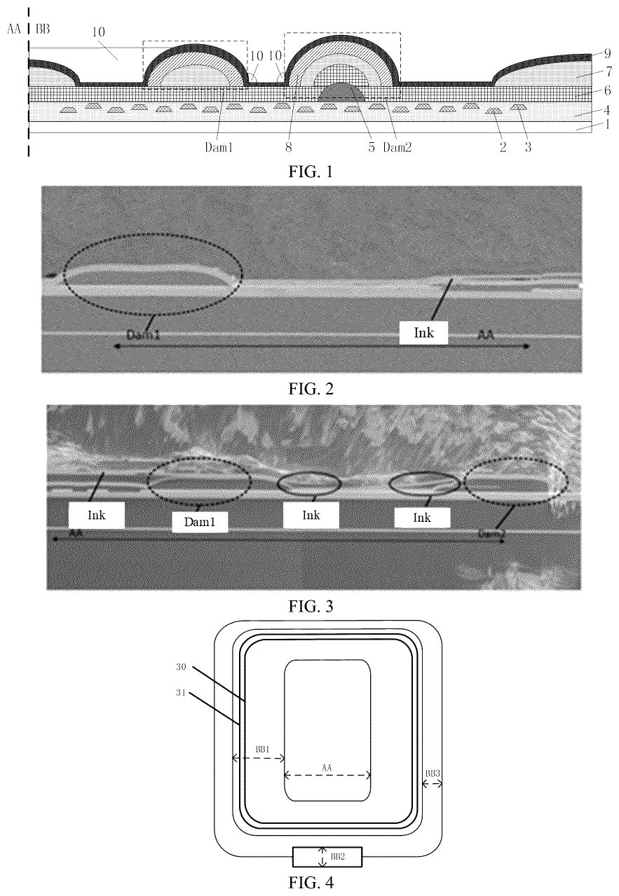

In the packaging of the OLED displaying devices using a flexible thin film, usually a dam structure is used to fix the ink within a certain space area, thereby the problem of overflowing of the ink is prevented. In the related art, usually a double-dam structure (Dam1 and Dam2 shown in FIG. 1) is used to block the ink, for the following reasons: it is usually desirable that the ink is cut off within Dam1, as shown in FIG. 2, in which the Dam1 can completely block the ink from overflowing. However, in the practical process, the ink comes over the Dam1 frequently due to process fluctuation, as shown in FIG. 3, the ink overflows to the Dam2 and then is cut off within the Dam2 (usually, the ink, after passing through the two dams, basically does not further overflow the Dam2). Accordingly, in the related art, usually two dams are disposed to prevent overflowing of the ink, wherein the Dam1 close to the displaying region AA serves to block a major part of the ink, and the Dam2 away from the displaying region AA serves for assurance.

With the progress of technology, the screens of displaying devices are larger and larger, for example, the full-screen displaying devices, and therefore it is urgently desired that the displaying devices have a narrower border frame. However, because each of the dams of the double-dam structure in the related art requires occupying a large room, and a certain spacing is further required to be kept between the two dams, resulting in that a narrower border frame cannot be further realized. In other words, the components disposed within the non-displaying region such as the dams and the metal wires may affect the design of the width of the non-displaying region, which causes that it is difficult for the displaying devices to realize a narrow border frame, and that the displaying devices have a low screen-to-body ratio, thereby the user experience is poor. In view of the above, the embodiments of the present application provide a displaying base plate and a displaying device, and the displaying base plate can effectively reduce the width of the non-displaying region, so as to realize a narrow border frame, and accordingly increase the screen-to-body ratio.

In order to achieve the above object, a displaying base plate is provided by an embodiment of the present application. Referring to FIG. 4, the displaying base plate includes: a displaying region AA and a non-displaying region surrounding the displaying region AA, and the non-displaying region includes a first dam region BB1, wherein the first dam region BB1 surrounds the displaying region AA.

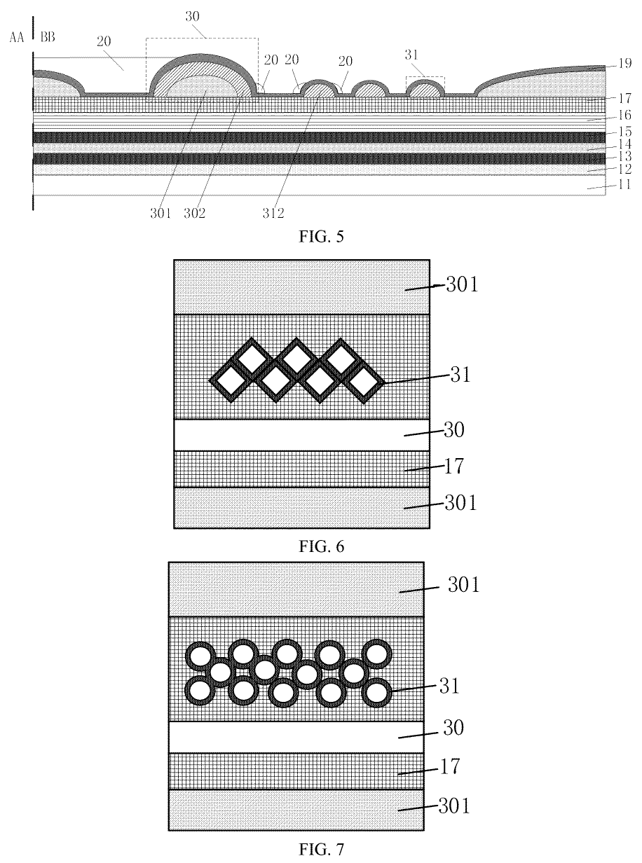

Referring to FIG. 4 and FIG. 5, the first dam region BB1 includes a dam 30, and at least one blocking unit 31 located at one side of the dam 30 away from the displaying region AA, the dam 30 and the blocking unit 31 are disposed within at least a part of the first dam region BB1, and the blocking unit 31 is patterned.

The displaying base plate stated above may be an OLED displaying base plate. The specific type of the displaying base plate is not limited herein.

The displaying region is also referred to as an active area (referred to for short as an AA region), and refers to the region within which a plurality of pixels are disposed to realize the displaying. The non-displaying region is generally used to dispose driving wirings, driving circuits and so on, for example, gate driver on array (GOA, array-base-plate line driving) driving circuits. The non-displaying region is an annular region surrounding the displaying region, and matches with the shape of the displaying region. For example, the shape of the displaying region is a rectangle, and the shape of the non-displaying region is a rectangular annular shape. The shape of the displaying region is a circle, and the shape of the non-displaying region is a circular annular shape.

The first dam region includes a dam and at least one blocking unit. The dam and the blocking unit used herein are configured to be capable of preventing ink overflowing in the formation of organic layers such as an organic luminescent functional layer and an organic packaging layer by ink-jet printing, so that the problem of invasion of water vapor and oxygen caused by ink overflowing in the formation of the organic layers by ink-jet printing can be solved by using the dam and the blocking unit.

The quantity and the structure of the blocking unit included by the first dam region are not limited herein. As an example, in order to further improve the effect of the prevention of ink overflowing, and realize a narrower border frame, the first dam region may include one blocking unit. Alternatively, in order to better improve the effect of the prevention of ink overflowing, and realize a narrower border frame, the first dam region may include two blocking units. Certainly, the first dam region may also include three or more blocking units, which is determined specifically by the amounts of the organic materials of the organic layers of the displaying base plate, the width of the non-displaying region and so on. FIG. 5 is illustrated by taking the case as an example in which the first dam region includes three blocking units 31, at this moment, while a narrower border frame of the displaying base plate can be realized, it can be also ensured that the organic materials of the organic layers does not overflow.

The specific structure of the blocking units is not limited herein. As an example, the blocking units may be of a single-layer structure. Alternatively, the blocking units may be of a multilayer structure. FIG. 5 is illustrated by taking the case as an example in which each of the blocking units includes a patterned first pixel defining part 312.

The quantity and the structure of the dam included by the first dam region are not specifically limited herein. As an example, in order to realize a narrower border frame, the first dam region may include one dam. Alternatively, in order to improve the effect of the prevention of ink overflowing, the first dam region may include a plurality of dams, for example, two dams. FIG. 5 is illustrated by taking the case as an example in which the first dam region includes one dam 30, at this moment, the dam 30 can block the organic packaging layer 20, and can effectively realize a narrower border frame.

The specific structure of the dam stated above is not limited herein. As an example, the dam may be of a single-layer structure. Alternatively, the dam may be of a multilayer structure. FIG. 5 is illustrated by taking the case as an example in which the dam 30 includes a second planarization part 301 and a second pixel defining part 302 that are arranged in layer configuration.

That the dam and the at least one blocking unit are disposed within at least a part of the first dam region refers to that, in order to enable a part of the non-displaying region to realize a narrower border frame, both of the dam and the at least one blocking unit may be disposed within a part of the first dam region, i.e., surrounding a part of the displaying region AA.

Alternatively, in order to realize a better effect of the prevention of ink overflowing, and enable a whole of the non-displaying region to realize a narrower border frame, both of the dam and the at least one blocking unit stated above may be disposed within the whole of the first dam region, i.e., surrounding the displaying region AA by one circle. FIG. 4 is illustrated by taking the case as an example in which both of one dam 30 and one blocking unit 31 surround the displaying region AA by one circle. FIG. 5 is illustrated by taking the case as an example in which all of one dam 30 and three blocking units 31 are disposed at the side of the first dam region close to the driving-circuit region, at this moment, a narrower border frame can be realized at the side of the first dam region close to the driving-circuit region.

The patterning of the blocking units refers to forming the required blocking units by using a patterning process of exposure, wherein the patterning process used herein includes processes such as mask, exposure, development, etching and stripping.

The embodiments of the present application provide a displaying base plate, wherein the displaying base plate includes: a displaying region; and a non-displaying region surrounding the displaying region, the non-displaying region includes a first dam region, wherein the first dam region surrounds the displaying region. The first dam region includes a dam, at least one blocking unit located at one side of the first dam region away from the displaying region, the dam and the blocking unit are disposed within at least a part of the first dam region, and the blocking unit is patterned. Thus, the width of the non-displaying region can be reduced more effectively, to realize a narrower border frame, and accordingly the screen-to-body ratio is greatly increased. The principle that a narrower border frame can be realized will be described by taking the displaying base plate shown in FIG. 5 as an example. Referring to FIG. 5, in an aspect, the displaying base plate includes one dam 30, which, as compared with the two dams (the Dam1 and the Dam2) disposed in the related art shown in FIG. 1, omits one dam, whereby the room of the non-displaying region occupied by the dams is effectively reduced, and at the same time the dam 30 can block most of the organic material in the organic packaging layer 20 from overflowing. In another aspect, the displaying base plate further includes three patterned blocking units 31. Because the blocking units 31 are patterned, they definitely occupy much less room than the dam. Moreover, the patterned blocking units 31 have irregular edges, and if a small amount of the organic material of the organic packaging layer 20 still overflows the dam 30, the edges of the patterned blocking units 31 can further cut off the organic material. Accordingly, based on that the overflowing of the organic material can be better prevented, a narrower border frame can be realized in the displaying base plate of the present application, thereby the screen-to-body ratio is increased, and a good user experience is obtained.

Optionally, in order to, on basis of realizing a better effect of the prevention of overflowing of the organic material, enable the displaying base plate to further realize the effect of a narrower border frame, referring to FIG. 4 and FIG. 5, the first dam region includes one dam.

The position of the one dam within the first dam region is not specifically limited herein. As an example, the one dam may be disposed within a part of the first dam region, i.e., surrounding a part of the displaying region AA. Alternatively, the one dam may be disposed within the whole of the first dam region, i.e., surrounding the displaying region AA by one circle. FIG. 4 is illustrated by taking the case as an example in which one dam 30 surrounds the displaying region AA by one circle. FIG. 5 is illustrated by taking the case as an example in which one dam 30 is disposed at the side of the first dam region close to the driving-circuit region, at this moment, a narrower border frame can be realized at the side of the first dam region close to the driving-circuit region.

The specific structure of the one dam stated above is not limited herein. As an example, the dam may be of a single-layer structure. Alternatively, the dam may be of a multilayer structure. FIG. 5 is illustrated by taking the case as an example in which the dam 30 includes a second planarization part 301 and a second pixel defining part 302 that are arranged in layer configuration.

Optionally, referring to FIG. 4, the non-displaying region further includes a driving-circuit region BB2, and the driving-circuit region BB2 is located at the side of the first dam region BB1 away from the displaying region AA.

Referring to FIG. 5, the dam 30 and the blocking unit 31 are disposed at least the side of the first dam region close to the driving-circuit region. That can enable at least one side of the driving-circuit region of the displaying base plate to realize a narrower border frame, and simplify the fabricating process, which more facilitates the practical production application, and is simple and easy to implement.

The driving-circuit region is also referred to as a fanout region, and is the region where the driving circuits, the lead wires and so on are disposed.

That the dam and the blocking unit are disposed at least the side of the first dam region close to the driving-circuit region refers to that the dam and the blocking units may be disposed at merely the side of the first dam region close to the driving-circuit region, at this moment, a narrower border frame can be merely realized at one side of the driving-circuit region of the displaying base plate, or the dam and the blocking units may be disposed at the side of the first dam region close to the driving-circuit region, and disposed at the side of the first dam region that is not closer to the driving-circuit region, for example, the dam and the blocking units stated above may be disposed within the whole of the first dam region, at this moment, a narrower border frame can be realized in the whole of the displaying base plate.

It should be noted that FIG. 5 is illustrated by taking the case as an example in which the dam 30 and the blocking units 31 are merely disposed at the side of the first dam region close to the driving-circuit region. Referring to FIG. 5, the displaying base plate further includes a substrate 11, and a first grid-line layer 12, a first insulating layer 13, a second grid-line layer 14, a second insulating layer 15, a source-drain wiring layer 16 and an inter-layer-medium layer 17 that are arranged in layer configuration on the substrate 11. Merely the contents that are relevant to the inventiveness are described herein, and the other components may be obtained with reference to the related art, and are not described in detail herein.

Optionally, in order to enable the periphery of the displaying base plate to realize a narrower border frame, referring to FIG. 4, the dam 30 and the blocking units 31 are disposed within the whole of the first dam region, and surround the displaying region.

FIG. 4 is illustrated by taking the case as an example in which one dam 30 and one blocking unit 31 surround the displaying region AA by one circle. Certainly, the quantity of the blocking unit may also be more than one, which is specifically determined according to practical applications.

Optionally, in order to enable the displaying base plate to further realize a narrower border frame, the blocking unit among the at least one blocking unit adjacent to the dam is connected to the dam.

When the displaying base plate includes a plurality of the blocking units, the mode of the provision of the blocking units other than the blocking unit adjacent to the dam is not specifically limited herein. As an example, the blocking units other than the blocking unit adjacent to the dam may be disposed adjacent to the blocking unit that is adjacent to the dam.

Alternatively, the blocking units other than the blocking unit adjacent to the dam may be separate from the blocking unit adjacent to the dam.

In the related art, referring to FIG. 1, the Dam1 and the Dam2 of the double-dam structure should not be connected, and there must be a certain spacing between the Dam1 and the Dam2, which may definitely increase the room occupied by the dams. In the displaying base plate according to the embodiments of the present application, because the blocking units are patterned, the patterned blocking units can be connected to the dam. Accordingly, by configuring that the blocking unit that is close to the dam is connected to the dam, the room occupied by the dam and the blocking units is further reduced, thereby a narrower border frame is further realized.

It should be noted that the blocking unit among the at least one blocking units adjacent to the dam may also be separate from the dam. FIG. 5 is illustrated by taking the case as an example in which the blocking units 31 and the dam 30 are separate and all of the neighboring blocking units 31 are separate from each other. The separation distance between the blocking unit adjacent to the dam and the dam is not specifically limited, as long as the distance is less than the spacing between the Dam1 and the Dam2 in the related art.

Optionally, referring to FIG. 5, the blocking unit includes a patterned protrusion. Accordingly, the fabricating process is convenient, and is simple and easy to implement.

The specific structure of the patterned protrusion is not limited herein. As an example, the patterned protrusion may include a single-layer structure; for example, it includes one layer of a planarization part or one layer of a pixel defining part. Alternatively, the patterned protrusion may include a multilayer structure; for example, it includes a planarization part, a pixel defining part and so on that are arranged in layer configuration. FIG. 5 is illustrated by taking the case as an example in which each of the patterned protrusions includes a first pixel defining part 312.

The height of the protrusion in the direction perpendicular to the substrate is not specifically limited herein. As an example, the range of the height of the protrusion in the direction perpendicular to the substrate may be 1.5-3 μm. The width of the protrusion in the direction parallel to the substrate is not specifically

limited herein. As an example, the range of the width of the protrusion in the direction parallel to the substrate may be 11-25 μm.

The shape of the protrusion is not specifically limited herein. As an example, the protrusion may include a rhombic column, a cylinder, a cylindrical ring and so on.

Optionally, referring to FIG. 5, the non-displaying region further includes a substrate 11, and the patterned protrusion is disposed on the substrate 11. The protrusion includes a first planarization part and/or a first pixel defining part 312. Accordingly, the protrusion can be formed by patterning simultaneously with the fabrication of the planarization layer and/or the pixel defining layer, which is simple and easy to implement.

The material of the substrate is not limited herein. It may include a rigid material, for example, a glass. Alternatively, it may also include a flexible material, for example, polyimide (PI).

The material of the first planarization part is not specifically limited herein. As an example, the material of the first planarization part may include an organic material. Specifically, the material of the first planarization part may include any one of a thermosetting polyimide-type material, an epoxy-type material and an acrylic acid type material.

The material of the first pixel defining part is not specifically limited herein. As an example, the material of the first pixel defining part may include an organic material. Specifically, the material of the first pixel defining part may include any one of a thermosetting polyimide-type material, an epoxy-type material and an acrylic acid type material.

The present application provides a first type of the structure of the patterned protrusion. In order to make that both of the height in the direction perpendicular to the substrate and the width in the direction parallel to the substrate of the blocking unit are low, optionally, when the protrusion includes the first planarization part, the first planarization part is patterned. At this moment, the blocking unit merely includes one layer, which further facilitates to realize a narrower border frame.

The present application provides a second type of the structure of the patterned protrusion. In order to make that both of the height in the direction perpendicular to the substrate and the width in the direction parallel to the substrate of the blocking unit are low, optionally, referring to FIG. 5, when the protrusion includes the first pixel defining part 312, the first pixel defining part 312 is patterned. At this moment, the blocking unit merely includes one layer, which further facilitate to realize a narrower border frame.

The present application provides a third type of the structure of the patterned protrusion. Optionally, when the protrusion includes the first planarization part and the first pixel defining part, the protrusion includes the first planarization part and the first pixel defining part that are arranged in layer configuration on the substrate, and the first planarization part is patterned.

The present application provides a fourth type of the structure of the patterned protrusion. Optionally, when the protrusion includes the first planarization part and the first pixel defining part, the protrusion includes the first planarization part and the first pixel defining part that are arranged in layer configuration on the substrate, and the first pixel defining part is patterned.

The present application provides a fifth type of the structure of the patterned protrusion. Optionally, when the protrusion includes the first planarization part and the first pixel defining part, the protrusion includes the first planarization part and the first pixel defining part that are arranged in layer configuration on the substrate, the first planarization part is patterned and the first pixel defining part is patterned.

Optionally, referring to FIG. 5, the non-displaying region further includes a packaging unit disposed at the side of the patterned protrusion away from the substrate 11, and the packaging unit covers the protrusion. Accordingly, the displaying base plate can be packaged, to effectively block water vapor, oxygen and so on from eroding the displaying base plate.

The structure of the packaging unit stated above is not specifically limited herein. As an example, the packaging unit may include a single-layer structure; for example, it may include one layer of a first inorganic packaging layer 19 shown in FIG. 5, and the first inorganic packaging layer 19 covers the protrusion. Alternatively, the packaging unit may include a multilayer structure; for example, it may include a first inorganic packaging layer, an organic packaging layer and a second inorganic packaging layer that are arranged in layer configuration, the first inorganic packaging layer and the second inorganic packaging layer are configured to package the first dam region, and the organic packaging layer is broken within the first dam region.

The specific materials of the first inorganic packaging layer and the second inorganic packaging layer are not limited. As an example, both of the materials of the first inorganic packaging layer and the second inorganic packaging layer may include any one of silicon nitride (SiNx), silicon oxide (SiOx), silicon oxynitride (SiON) and aluminium oxide (AlOx), and the combination of one or more of silicon nitride (SiNx), silicon oxide (SiOx), silicon oxynitride (SiON) and aluminium oxide (AlOx).

The first inorganic packaging layer and the second inorganic packaging layer may be fabricated by a process of chemical vapor deposition, but are not limited thereto. Alternatively, they may also be formed by a process of physical vapor deposition and so on. The organic packaging layer may be fabricated by a process of ink-jet printing, but is not limited thereto. Alternatively, it may also be formed by a process of spray coating. In the fabrication of the organic packaging layer, because the organic packaging material has a certain fluidity, it is required to dispose the dam and the blocking units within the first dam region, to block the organic packaging material from overflowing, thereby the problem of packaging failure is avoided.

Optionally, in order to improve the effect of the prevention of ink overflowing, and realize a narrower border frame, the first dam region includes two blocking units.

The structures of the two blocking units are not specifically limited herein. As an example, the structures of the two blocking units may be the same; for example, both of them include a single-layer structure or both of them include a multilayer structure. Alternatively, the structures of the two blocking units may be different; for example, one of the blocking units includes a single-layer structure, and the other blocking unit includes a multilayer structure.

Optionally, referring to FIGS. 6-8, the shape of the orthographic projection of the patterned protrusion in the direction perpendicular to the substrate includes a planar shape or an annular shape.

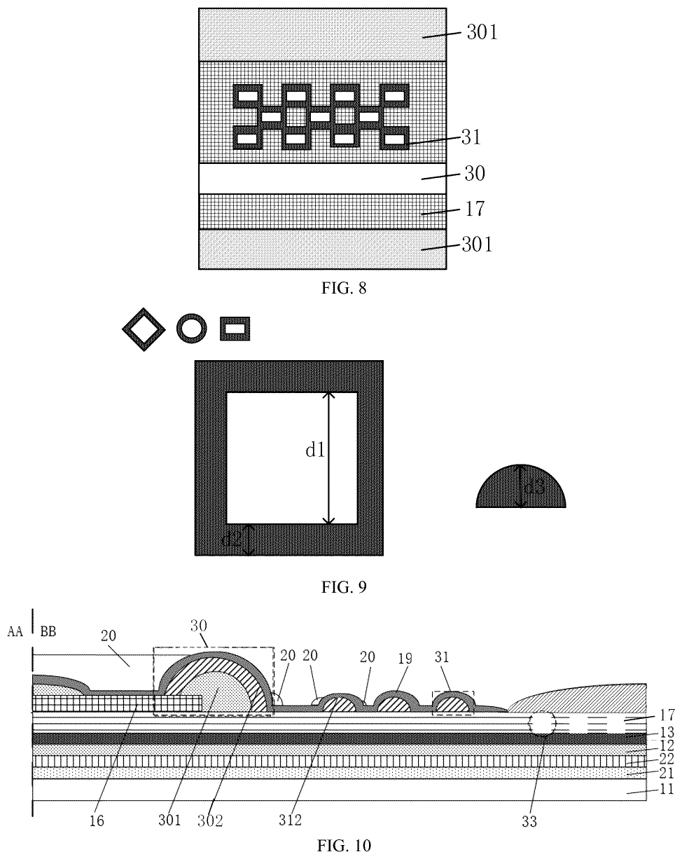

The specific shape of the orthographic projection of the protrusion in the direction perpendicular to the substrate is not limited herein. As an example, the particular shape of the orthographic projection of the patterned protrusion in the direction perpendicular to the substrate may include a single regular pattern, for example, a rhombus or rhombic ring, a rectangle or rectangular ring, a circle or circular ring, a triangle or triangular ring, and an ellipse or elliptical ring. Alternatively, the specific shape of the orthographic projection of the patterned protrusion in the direction perpendicular to the substrate may include a combination of multiple regular patterns, for example, a combination of a rhombic ring and a rectangular ring, a combination of a circular ring and an elliptical ring, and a combination of a triangle and a rectangular ring. FIG. 6 is illustrated by taking the case as an example in which the shape of the orthographic projection of the protrusion in the direction perpendicular to the substrate includes a rhombic ring. FIG. 7 is illustrated by taking the case as an example in which the shape of the orthographic projection of the protrusion in the direction perpendicular to the substrate includes a circular ring. FIG. 8 is illustrated by taking the case as an example in which the shape of the orthographic projection of the protrusion in the direction perpendicular to the substrate includes a rectangular ring.

Optionally, referring to FIGS. 6-8, when the shape of the orthographic projection of the patterned protrusion in the direction perpendicular to the substrate includes an annular shape, the dam region includes a plurality of patterned protrusions, and at least some of the neighboring patterned protrusions are connected. Accordingly, not only the edges of the patterned protrusions can be used to block ink overflowing, but also, when the ink overflows the edges of the patterned protrusions, the protruding hollow ring can further block the ink overflowing, in this way, ink overflowing is effectively blocked in multiple aspects.

That at least some of the neighboring patterned protrusions are connected refers to that some of the neighboring patterned protrusions are connected, or all of the neighboring patterned protrusions are connected. All of FIGS. 6-8 are illustrated by taking the case as an example in which some of the neighboring patterned protrusions are connected.

The pattern formed after at least some of the neighboring patterned protrusions are connected is not specifically limited herein. As an example, the pattern formed after at least some of the neighboring patterned protrusions are connected may be a regular pattern, for example, a rectangular ring, and a rhombic ring. Alternatively, the pattern formed after at least some of the neighboring patterned protrusions are connected may be an irregular pattern. All of FIGS. 6-8 are illustrated by taking the case as an example in which the pattern formed after some of the neighboring patterned protrusions are connected is an irregular pattern.

When some of the neighboring patterned protrusions are connected, the positions of the some of the neighboring patterned protrusions that are connected and the dam are not specifically limited. As an example, the some of the neighboring patterned protrusions that are connected may be adjacent to the dam, at this moment, the some of the neighboring patterned protrusions that are connected may be connected to or separate from the dam. Alternatively, other patterned protrusions may also be disposed between the some of the neighboring patterned protrusions that are connected and the dam.

When all of the neighboring patterned protrusions are connected, the positions of the all of the neighboring patterned protrusions that are connected and the dam are not specifically limited. As an example, the all of the neighboring patterned protrusions that are connected are separate from the dam. Alternatively, the all of the neighboring patterned protrusions that are connected are connected to the dam.

Optionally, referring to FIG. 9, the range of the height d3 of the cross section of the patterned protrusion perpendicular to the substrate is 1.5-3 μm. In the related art, the cross section of the Dam2 perpendicular to the substrate has a greater height, which is usually higher than the height of the cross section of the Dam1 perpendicular to the substrate. Accordingly, in the present application, by configuring that the range of the height of the cross section of the patterned protrusion perpendicular to the substrate is 1.5-3 μm, the height of the cross section of the blocking unit perpendicular to the substrate is less than the height of the dam, so as to realize a narrow border frame better.

The range of the height of the cross section of the patterned protrusion perpendicular to the substrate is not specifically limited herein. As an example, the height of the cross section of the patterned protrusion perpendicular to the substrate may be 1.5 μm, 2 μm, 2.5 μm, 3 μm and so on.

Optionally, referring to FIG. 9, the range of the width (d1+2d2) of the orthographic projection of the patterned protrusion in the direction perpendicular to the substrate is 11-25 μm. In the related art, the orthographic projection of the Dam2 in the direction perpendicular to the substrate has a greater width, which is usually greater than the width of the orthographic projection of the Dam1 in the direction perpendicular to the substrate. Accordingly, in the present application, by configuring that the range of the width of the orthographic projection of the patterned protrusion in the direction perpendicular to the substrate is 11-25 μm, the width of the orthographic projection of the blocking unit in the direction perpendicular to the substrate is less than the width of the dam, and is much less than the width of the orthographic projection of the Dam2 in the direction perpendicular to the substrate in the related art, so as to realize a narrow border frame better.

The range of the width of the orthographic projection of the patterned protrusion in the direction perpendicular to the substrate is not specifically limited herein. As an example, the width of the orthographic projection of the patterned protrusion in the direction perpendicular to the substrate may be 11 μm, 15 μm, 20 μm, 25 μm and so on.

Optionally, referring to FIG. 9, when the shape of the orthographic projection of the patterned protrusion in the direction perpendicular to the substrate includes an annular shape, the range of the width dl of the inner ring of the annular shape in the direction parallel to the substrate is 5-15 μm. Accordingly, the orthographic projection of the blocking unit in the direction perpendicular to the substrate has a low width, so as to realize a narrow border frame better.

The range of the width of the inner ring of the annular shape in the direction parallel to the substrate is not specifically limited herein. As an example, the width of the inner ring of the annular shape in the direction parallel to the substrate may be 5 μm, 8 μm, 11 μm, 15 μm and so on.

It should be noted that, according to the range of the width (d1+2d2) of the orthographic projection of the patterned protrusion in the direction perpendicular to the substrate, and the range of the width d1 of the inner ring of the annular shape in the direction parallel to the substrate, it can be obtained that d2 shown in FIGS. 6-8 ranges 3-5 μm, and may specifically be 3 μm, 4 μm or 5 μm.

Optionally, referring to FIG. 4, the non-displaying region further includes a crack dam region BB3, and the crack dam region BB3 surrounds the first dam region BB1, and is broken within the driving-circuit region BB2. The crack dam region BB3 includes at least one slot, and the slot surrounds the first dam region BB1, and is broken within the driving-circuit region BB2.

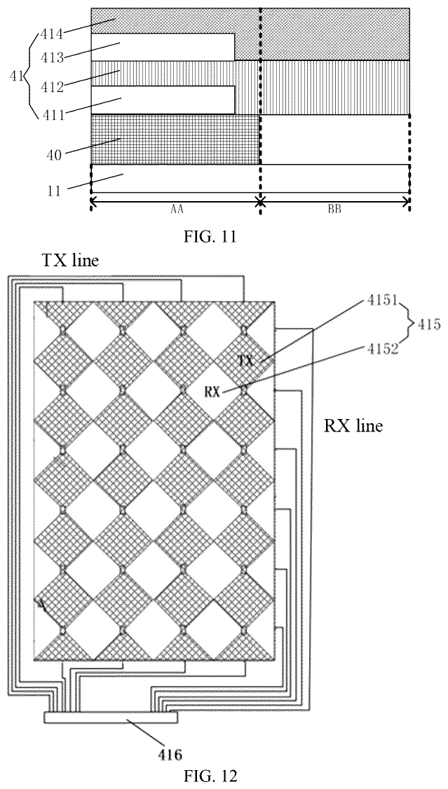

Referring to FIGS. 4 and 10, the crack dam region BB3 includes at least one slot 33, and the slot 33 surrounds the first dam region BB1, and is broken within the driving-circuit region BB2.

The quantity of the slot is not limited. FIG. 10 is illustrated by taking three slots 33 that are arranged continuously and separately as an example. The slot can reduce and distribute the stress generated in cutting, thereby the risk in crack in cutting is reduced. Therefore, the slot may also be referred to as a crack dam. The depth of the slot in the direction perpendicular to the substrate is not limited, and may be determined according to practical situations.

It should be noted that, when the driving-circuit region employs a pad bending structure (in other words, the pad region is bent to the non-displaying surface of the base plate), then the disconnection position of the slot corresponds to the driving-circuit region (fanout region) within the bends region. When the driving-circuit region does not employ the pad bending structure, then the disconnection position of the slot corresponds to the pad region (bonding region).

Optionally, referring to FIG. 10, the non-displaying region further includes a buffer layer 21, a gate insulating layer 22 and an inter-layer-medium layer 17 that are arranged in layer configuration. All of the inter-layer-medium layer 17, the gate insulating layer 22 and the buffer layer 21 are located within the displaying region AA, the first dam region BB1 and the crack dam region BB3. The slot extends throughout at least the part of the inter-layer-medium layer 17 that is located within the crack dam region BB3.

It should be noted that the slot 33 may, as shown in FIG. 10, extend throughout merely the part of the inter-layer-medium layer 17 that is located within the crack dam region BB3. Alternatively, the slot may also extend throughout the parts of both of the inter-layer-medium layer and the gate insulating layer that are located within the crack dam region. Alternatively, the slot may also extend throughout the parts of all of the inter-layer-medium layer, the gate insulating layer and the buffer layer that are located within the crack dam region, which is not limited herein.

Optionally, referring to FIG. 11, the displaying base plate further includes a substrate 11, and a driving unit 40 and a touch unit 41 that are disposed on the substrate 11. The driving unit 40 is located within the displaying region AA, and the touch unit 41 is located within the displaying region AA and the non-displaying region BB, and covers the driving unit 40.

The structure of the touch unit is not limited. As an example, the touch unit may employ a mutual capacitive touch structure or a self-capacitive touch structure. The mutual capacitive touch structure or the self-capacitive touch structure may be obtained in the related art, and is not described in detail herein.

Optionally, referring to FIG. 11, the touch unit 41 includes a first touch layer 411, a first insulating layer 412, a second touch layer 413 and a second insulating layer 414 that are arranged in layer configuration on the driving unit 40. Both of the first touch layer 411 and the second touch layer 413 are located within the displaying region AA, and the first insulating layer 412 and the second insulating layer 414 are located within the displaying region AA and the non-displaying region BB. One of the first touch layer 411 and the second touch layer 413 is a metal-grid electrode layer, and the other is a bridging metal layer.

The first touch layer may be a metal-grid electrode layer, and at the same time the second touch layer may be a bridging metal layer. Alternatively, the first touch layer may be a bridging metal layer, and at the same time the second touch layer may be a metal-grid electrode layer. In order to obtain a good effect of the touch controlling, the latter may be selected.

Referring to FIG. 12, the metal-grid electrode layer 415 may include driving electrodes (TX electrodes) 4151 and sensing electrodes (RX electrodes) 4152. Each column of the driving electrodes 4151 are directly connected, and are electrically connected to the touch driving unit 416 by TX lines. Each row of the sensing electrodes 4152 are electrically connected to the bridging metal layer by via holes extending throughout the first insulating layer, and are electrically connected to the touch driving unit 416 by RX lines. The metal-grid electrode layer 415 may be located within the displaying region, and the TX lines, the RX lines and the touch driving unit may be located within the non-displaying region. The structure of the touch unit is an FMLOC (Flexible Multi-Layer On Cell) touch structure. Such a touch structure can reduce the screen thickness to facilitate the folding, does not have an adhesion tolerance to reduce the width of the border frame, and can reduce the risk in crack.

The materials of the first insulating layer and the second insulating layer may be any one of silicon nitride, silicon oxide and silicon oxynitride.

The displaying base plate according to the embodiments of the present application can more effectively reduce the width of the non-displaying region, to realize a narrower border frame, and accordingly greatly increase the screen-to-body ratio.

An embodiment of the present application further provides a displaying device, wherein the displaying device includes the displaying base plate stated above.

The displaying device may be a displaying device having the function of touch controlling, may also be a displaying device having the function of folding or curling, or may also be a displaying device having both of the functions of touch controlling and folding at the same time, which is not limited herein. The displaying device may be a flexible displaying device (also referred to as a flexible screen), and may also be a rigid displaying device (i.e., a display screen that cannot be bent), which is not limited herein.

The displaying device may be an OLED displaying device, a Micro LED displaying device or a Mini LED displaying device.

The displaying device may be any product or component having a displaying function, such as a television set, a digital camera, a mobile phone and a tablet personal computer. The displaying device may also be applied in fields such as identity identification and medical equipment, and the products that have already been promoted or have a good prospect of promotion include security identity authentication, smart door locks, medical video collection and so on. The displaying device has the advantages such as a very narrow border frame, a good effect of packaging, a low cost, a good effect of displaying, a long life, a high stability, a high contrast, a good imaging quality and a high product quality.

The “embodiment” as used herein means that particular features, structures or characteristics described with reference to an embodiment are included in at least one embodiment of the present application.

The description provided herein describes many concrete details. However, it can be understood that the embodiments of the present application may be implemented without those concrete details. In some of the embodiments, well-known processes, structures and techniques are not described in detail, so as not to obscure the understanding of the description.

Finally, it should be noted that the above embodiments are merely intended to explain the technical solutions of the present application, and not to limit them. Although the present application is explained in detail with reference to the above embodiments, a person skilled in the art should understand that he can still modify the technical solutions set forth by the above embodiments, or make equivalent substitutions to a part of the technical features of them. However, those modifications or substitutions do not make the essence of the corresponding technical solutions depart from the spirit and scope of the technical solutions of the embodiments of the present application.

1. A displaying base plate, wherein the displaying base plate comprises:
a displaying region; and
a non-displaying region surrounding the displaying region, comprising a first dam region, wherein the first dam region surrounds the displaying region;
wherein the first dam region comprises a dam, at least one blocking unit located at one side of the dam away from the displaying region, the dam and the blocking unit are disposed within at least a part of the first dam region, and the blocking unit is patterned.

2. The displaying base plate according to claim 1, wherein the first dam region comprises one dam.

3. The displaying base plate according to claim 2, wherein the non-displaying region further comprises a driving-circuit region, and the driving-circuit region is located at one side of the first dam region away from the displaying region; and
the dam and the blocking unit are disposed at least one side of the first dam region close to the driving-circuit region.

4. The displaying base plate according to claim 3, wherein the dam and the blocking unit are disposed within a whole of the first dam region, and surround the displaying region.

5. The displaying base plate according to claim 2, wherein the blocking unit among the at least one blocking unit adjacent to the dam is connected to the dam.

6. The displaying base plate according to claim 2, wherein the blocking unit comprises a patterned protrusion.

7. The displaying base plate according to claim 6, wherein the non-displaying region further comprises a substrate, and the patterned protrusion is disposed on the substrate; and
the protrusion comprises a first planarization part and/or a first pixel defining part.

8. The displaying base plate according to claim 7, wherein when the protrusion comprises the first planarization part, the first planarization part is patterned; or
when the protrusion comprises the first pixel defining part, the first pixel defining part is patterned.

9. The displaying base plate according to claim 7, wherein when the protrusion comprises the first planarization part and the first pixel defining part, the protrusion comprises the first planarization part and the first pixel defining part that are arranged in layer configuration on the substrate, and the first planarization part is patterned and/or the first pixel defining part is patterned.

10. The displaying base plate according to claim 7, wherein the non-displaying region further comprises a packaging layer disposed at one side of the patterned protrusion away from the substrate, and the packaging layer covers the protrusion.

11. The displaying base plate according to claim 2, wherein the first dam region comprises two blocking units.

12. The displaying base plate according to claim 7, wherein a shape of an orthographic projection of the patterned protrusion in a direction perpendicular to the substrate comprises a planar shape or an annular shape.

13. The displaying base plate according to claim 12, wherein when the shape of the orthographic projection of the patterned protrusion in the direction perpendicular to the substrate comprises the annular shape, the dam region comprises a plurality of patterned protrusions, and at least some neighboring patterned protrusions are connected.

14. The displaying base plate according to claim 12, wherein a range of a height of a cross section of the patterned protrusion perpendicular to the substrate is 1.5-3 μm.

15. The displaying base plate according to claim 12, wherein a range of a width of the orthographic projection of the patterned protrusion in the direction perpendicular to the substrate is 11-25 μm.

16. The displaying base plate according to claim 12, wherein when the shape of the orthographic projection of the patterned protrusion in the direction perpendicular to the substrate comprises the annular shape, a range of a width of an inner ring of the annular shape in a direction parallel to the substrate is 5-15 μm.

17. The displaying base plate according to claim 2, wherein the non-displaying region further comprises a crack dam region, and the crack dam region surrounds the first dam region, and is broken within the driving-circuit region; and
the crack dam region comprises at least one slot, and the slot surrounds the first dam region, and is broken within the driving-circuit region.

18. The displaying base plate according to claim 17, wherein the non-displaying region further comprises a buffer layer, a gate insulating layer and an inter-layer-medium layer that are arranged in layer configuration;
all of the inter-layer-medium layer, the gate insulating layer and the buffer layer are located within the displaying region, the first dam region and the crack dam region; and
the slot extends throughout at least a part of the inter-layer-medium layer that is located within the crack dam region.

19. The displaying base plate according to claim 1, wherein the displaying base plate further comprises a substrate, and a driving unit and a touch unit that are disposed on the substrate; and
the driving unit is located within the displaying region, and the touch unit is located within the displaying region and the non-displaying region, and covers the driving unit.

20. (canceled)

21. A displaying device, wherein the displaying device comprises the displaying base plate according to claim 1.
